(19) United States
(12) Patent Application Publication
(10) Pub. No.: US 2026/0182451 A1
(43) Pub. Date: Jun. 25, 2026

(54) LIGHT-EMITTING SUBSTRATE AND DISPLAY DEVICE

(71) Applicant: BOE Technology Group Co., Ltd., Beijing (CN)

(72) Inventor: Haixu LI, Beijing (CN)

(21) Appl. No.: 18/729,668

(22) PCT Filed: Apr. 27, 2023
(86) PCT No.: PCT/CN2023/091181

§ 371 Date: Jul. 17, 2024

(51) Int. Cl. H10W 90/00

(52) U.S. Cl. CPC H10W 90/00

(57) ABSTRACT

The present disclosure discloses a light-emitting substrate and a display device. The light-emitting substrate includes: a driving backplane; a plurality of light-emitting units disposed at a side of the driving backplane, where each light-emitting unit includes at least one light-emitting chip; and an encapsulation structure disposed between the driving backplane and the light-emitting unit and surrounding the light-emitting unit.

### CROSS-REFERENCE TO RELATED APPLICATIONS

This application is a National Stage of International Application No. PCT/CN2023/091181, filed on Apr. 27, 2023, all of which is hereby incorporated by reference in its entirety.

### TECHNICAL FIELD

The disclosure relates to the technical field of miniature LED display, and in particular, relates to a light-emitting substrate and a display device.

### BACKGROUND

Light-emitting diodes (LEDs) are widely used in lighting and display technology due to their advantages of a small size, a low power, a long service life, high brightness and active luminescence. The miniature LED, also known as the micro LED, mLED or μLED, is a new type of flat panel display technology. The miniature LED displays have LED arrays with individual pixel components. Compared with the widely used liquid crystal displays, the miniature LED displays have better contrast, a faster response speed, and lower energy consumption.

### SUMMARY

The present disclosure provides a light-emitting substrate and a display device, and specific solutions are as follows.

A light-emitting substrate provided by the present disclosure includes:
a driving backplane;
a plurality of light-emitting units disposed at a side of the driving backplane, each light-emitting unit including at least one light-emitting chip;
an encapsulation structure disposed between the driving backplane and the light-emitting unit and surrounding the light-emitting unit.

In a possible implementation, in the light-emitting substrate according to embodiments of the present disclosure, the driving backplane has a plurality of pads, the light-emitting chip includes a light-emitting main body and pins, and the light-emitting main body is electrically connected with corresponding pads through the pins. The encapsulation structure is disposed between the light-emitting main body and the driving backplane, and a thickness of the encapsulation structure is equal to a distance between a bottom surface of a side of the pad facing away from the light-emitting main body and the light-emitting main body.

In a possible implementation, in the light-emitting substrate according to embodiments of the present disclosure, the encapsulation structure includes a first encapsulation layer and a second encapsulation layer that are stacked; the first encapsulation layer and the pin are disposed in the same layer, and a thickness of the first encapsulation layer is equal to a thickness of the pin; and the second encapsulation layer and the pad are disposed in the same layer, and a surface of the second encapsulation layer facing the driving backplane is flush with a surface of the pad facing the driving backplane.

In a possible implementation, the light-emitting substrate according to embodiments of the present disclosure further includes a connection layer between the pads and the pins, and a heightening layer between the first encapsulation layer and the second encapsulation layer; and a thickness of the heightening layer is equal to a thickness of the connection layer.

In a possible implementation, in the light-emitting substrate according to embodiments of the present disclosure, a material of the heightening layer is the same as a material of the connection layer.

In a possible implementation, in the light-emitting substrate according to embodiments of the present disclosure, a material of the encapsulation structure is an inorganic material or an organic material.

In a possible implementation, in the light-emitting substrate according to embodiments of the present disclosure, the encapsulation structure is disposed at a side of the light-emitting main body; or the encapsulation structure is disposed at a side of the driving backplane.

In a possible implementation, in the light-emitting substrate according to embodiments of the present disclosure, the driving backplane includes a via hole region disposed at an outer side of the light-emitting unit, and an orthographic projection of the encapsulation structure on a substrate of the driving backplane and an orthographic projection of the via hole region on the substrate of the driving backplane do not overlap.

In a possible implementation, in the light-emitting substrate according to embodiments of the present disclosure, a shape of the encapsulation structure is a regular closed ring.

In a possible implementation, in the light-emitting substrate according to embodiments of the present disclosure, a shape of the encapsulation structure is an irregular closed ring avoiding the via hole region.

In a possible implementation, in the light-emitting substrate according to embodiments of the present disclosure, a distance between the encapsulation structure and the pin is greater than or equal to 5 μm, a width of the encapsulation structure is greater than or equal to 10 μm, and a distance between encapsulation structures outside two adjacent light-emitting units is greater than or equal to 3 μm.

In a possible implementation, the light-emitting substrate according to embodiments of the present disclosure further includes supporting structures independently disposed between the encapsulation structure and the light-emitting chip, where a thickness of the supporting structure is equal to a thickness of the encapsulation structure.

In a possible implementation, in the light-emitting substrate according to embodiments of the present disclosure, a plurality of supporting structures are provided, and the plurality of supporting structures are uniformly disposed between the encapsulation structure and the light-emitting chip.

In a possible implementation, in the light-emitting substrate according to embodiments of the present disclosure, a distance between the supporting structure and the pin is greater than or equal to 1.2 μm.

In a possible implementation, in the light-emitting substrate according to embodiments of the present disclosure, a material of the supporting structure is an organic material, and a shape of an orthographic projection of the supporting structure on the driving backplane includes a rectangle or a circle.

In a possible implementation, in the light-emitting substrate according to embodiments of the present disclosure, the encapsulation structure is disposed at an outer side of each light-emitting unit.

In a possible implementation, in the light-emitting substrate according to embodiments of the present disclosure, the number of encapsulation structures disposed at an outer side of each light-emitting unit is more than one, and encapsulation structures at the outer side of the same light-emitting unit are disposed at intervals.

In a possible implementation, in the light-emitting substrate according to embodiments of the present disclosure, the light-emitting unit includes a first light-emitting chip, a second light-emitting chip and a third light-emitting chip with different light-emitting colors; the pins include an anode pin and a cathode pin; anode pins of the first light-emitting chip, the second light-emitting chip and the third light-emitting chip are disposed independently from each other; and cathode pins of the first light-emitting chip, the second light-emitting chip and the third light-emitting chip are the same pin.

In a possible implementation, in the light-emitting substrate according to embodiments of the present disclosure, the light-emitting chip includes a Micro LED or a Mini LED.

Correspondingly, the present disclosure further provides a display device including the light-emitting substrate according to embodiments of the present disclosure.

### BRIEF DESCRIPTION OF FIGURES

FIG. 1 is a schematic diagram of a planar structure of a light-emitting substrate according to an embodiment of the present disclosure.

FIG. 2A is a schematic diagram of a sectional structure along a direction of CC′ in FIG. 1.

FIG. 2B is a structural diagram of a light-emitting chip in FIG. 2A.

FIG. 2C is a structural diagram of a driving backplane in FIG. 2A.

FIG. 3A is a schematic diagram of another sectional structure along the direction of CC′ in FIG. 1.

FIG. 3B is a structural diagram of a light-emitting chip in FIG. 3A.

FIG. 3C is a structural diagram of a driving backplane in FIG. 3A.

FIG. 3D is a structural diagram of a light-emitting chip in FIG. 3A.

FIG. 3E is a structural diagram of a driving backplane in FIG. 3A.

FIG. 4 is a schematic diagram of another sectional structure of a light-emitting substrate according to an embodiment of the present disclosure.

FIG. 5 is a schematic diagram of another sectional structure of a light-emitting substrate according to an embodiment of the present disclosure.

FIG. 6 is a schematic diagram of a planar structure corresponding to an encapsulation structure in FIGS. 4 and 5.

FIG. 7 is a schematic diagram of another planar structure corresponding to the encapsulation structure in FIGS. 4 and 5.

FIG. 8 is a schematic diagram of another sectional structure of a light-emitting substrate according to an embodiment of the present disclosure.

FIG. 9 is a schematic diagram of another sectional structure of a light-emitting substrate according to an embodiment of the present disclosure.

FIG. 10 is a schematic diagram of another planar structure corresponding to an encapsulation structure at an outer side of a light-emitting unit.

FIG. 11 is a schematic diagram of another planar structure corresponding to an encapsulation structure at an outer side of a light-emitting unit.

### DETAILED DESCRIPTION

For making objectives, technical solutions and advantages of embodiments of the present disclosure clearer, technical solutions of embodiments of the present disclosure will be clearly and completely described below in conjunction with accompanying drawings in embodiments of the present disclosure. Apparently, embodiments described are some rather than all of embodiments of the present disclosure. Embodiments in the present disclosure and features of embodiments may be combined with each other without conflict. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. “Including”, “comprising”, and other similar words used in the present disclosure indicate that elements or objects before the word include elements or objects after the word and their equivalents, without excluding other elements or objects. Words such as “connection” or “link”, etc., are not limited to physical or mechanical connections, but may include electrical connections, whether direct or indirect. “Inner”, “outer”, “upper”, “lower”, etc., are only used to indicate a relative positional relationship, and when an absolute position of a described object changes, the relative positional relationship may also change accordingly.

It should be noted that a size and a shape of each figure in the drawings do not reflect a true scale, but only for illustrating the present disclosure. Throughout the drawings, identical or similar reference numerals denote identical or similar elements or elements having identical or similar functions.

Light-emitting diode (LED) chips, as a key technology in a display technology, have become a trend in the display industry. A smaller LED size makes it easier to achieve high resolution, such as 4K or even 8K resolution for smartphones or virtual reality devices.

For virtual reality devices, response time of the organic light-emitting diode (OLED) panel has been reduced to a microsecond level, which has a very good response time level, and has become the most ideal choice for virtual reality applications. The LED chips may include mini light-emitting diode (Mini LED) chips and micro light-emitting diode (Micro LED) chips. Response time of the Micro LED can be reduced to a nanosecond level, which is 1000 times faster than the OLED. In addition, the Micro LED display devices have greater advantages in contrast, color gamut and flexible display.

However, at present, when encapsulating the LED, there is a gap between the LED and the driving backplane after bonding, resulting in that the liquid penetrates into the gap to cause the failure of the device in the subsequent processes of electroplating, etching and the like.

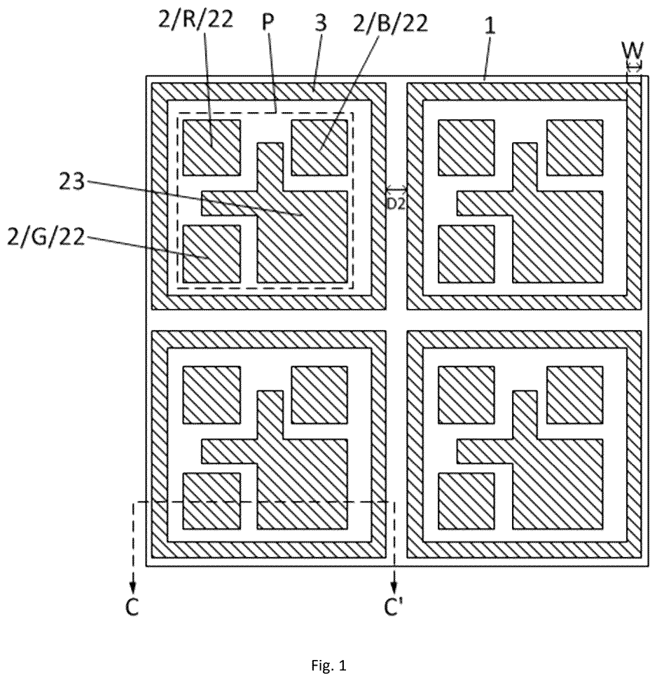

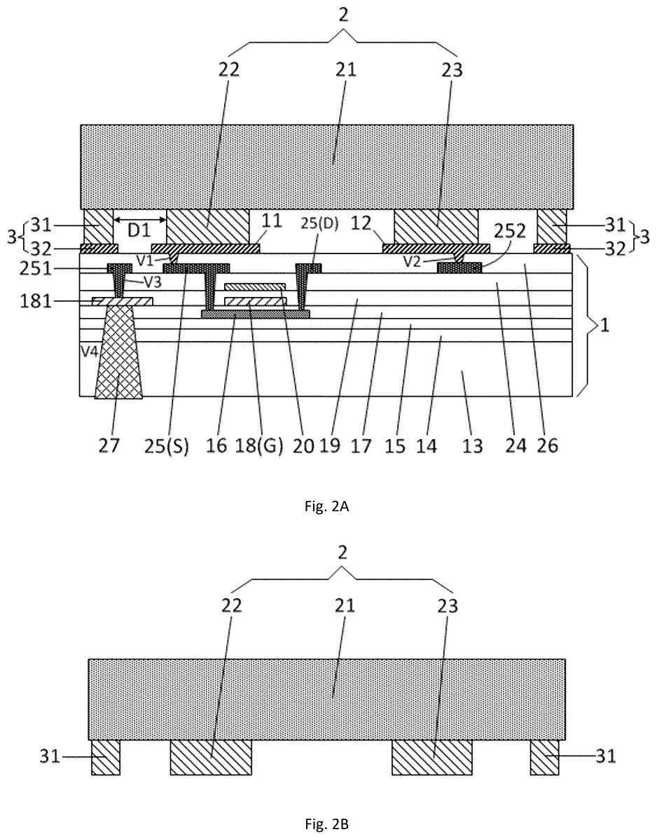

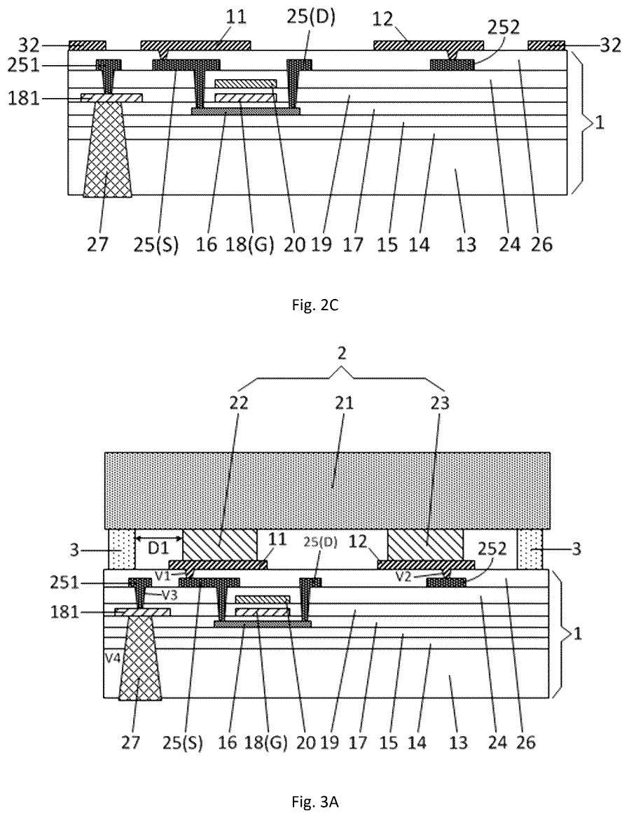

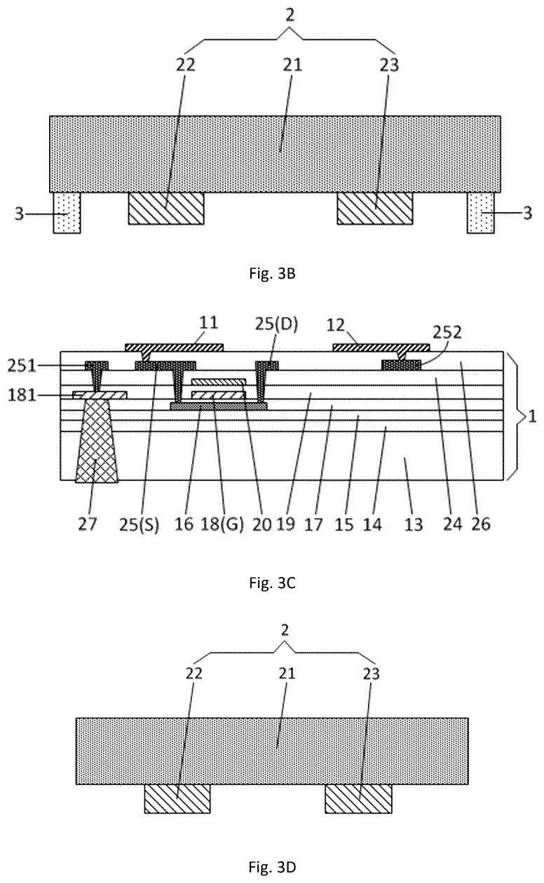

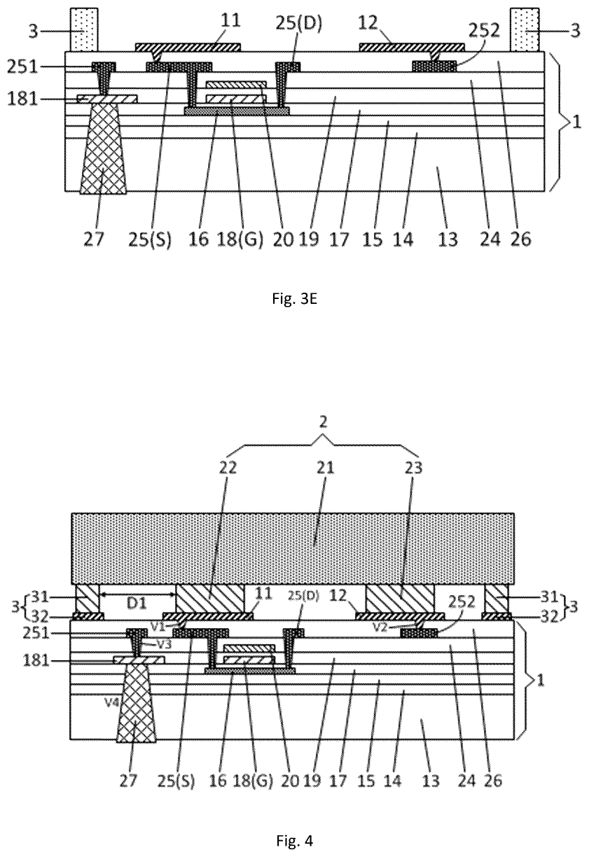

In order to solve the above problem, the present disclosure provides a light-emitting substrate, as shown in FIGS. 1, 2A and 3A. FIG. 1 is a schematic diagram of a planar structure of a light-emitting substrate, FIG. 2A is a schematic diagram of a sectional structure along a direction of CC′ in FIG. 1, and FIG. 3A is a schematic diagram of another sectional structure along the direction of CC′ in FIG. 1. The light-emitting substrate includes:
a driving backplane 1;
a plurality of light-emitting units P disposed at a side of the driving backplane 1, where each light-emitting unit P includes at least one light-emitting chip 2; specifically, FIG. 1 takes four light-emitting units P as an example, and the number of the light-emitting units P may be more, which is not limited in the present disclosure; and
an encapsulation structure 3 disposed between the driving backplane 1 and the light-emitting unit P and surrounding the light-emitting unit P.

In the light-emitting substrate according to embodiments of the present disclosure, by disposing the encapsulation structure which surrounds the light-emitting unit and is between the driving backplane and the light-emitting unit, each light-emitting unit can be protected and encapsulated independently to form an integral sealing structure for the light-emitting unit, effectively preventing liquid from infiltrating into the gap between the light-emitting chip and the driving backplane in the subsequent processes of electroplating, etching, cleaning and the like, so that the overall reliability and the stability of the device structure can be improved. Meanwhile, the encapsulation structure can also play a role in supporting the light-emitting substrate and improve the structural stability of the light-emitting substrate.

In a specific implementation, in the above light-emitting substrate according to embodiments of the present disclosure, as shown in FIGS. 2A and 3A, the driving backplane 1 has a plurality of pads (11 and 12), for example, the pad 11 is an anode pad, and the pad 12 is a cathode pad. The light-emitting chip 2 includes a light-emitting main body 21 and pins (22 and 23), for example, the pin 22 is an anode pin, and the pin 23 is a cathode pin. The light-emitting main body 21 is electrically connected with corresponding pads (11 and 12) through the pins (22 and 23). For example, the anode pin (22) of the light-emitting main body 21 is electrically connected with the anode pad (11), and the cathode pin (23) of the light-emitting main body 21 is electrically connected with the cathode pad (12).

The encapsulation structure 3 is disposed between the light-emitting main body 21 and the driving backplane 1, and a thickness of the encapsulation structure 3 is equal to a distance between a bottom surface of a side of the pads (11 and 12) facing away from the light-emitting main body 21 and the light-emitting main body 21. Therefore, a better bonding effect between the driving backplane 1 and the light-emitting chip 2 can be achieved, and the overall structural stability and the device reliability are improved.

In a specific implementation, in the above light-emitting substrate according to embodiments of the present disclosure, as shown in FIGS. 2A, 2B and 2C, FIG. 2B is a structural diagram of a light-emitting chip 2 in FIG. 2A, and FIG. 2C is a structural diagram of a driving backplane 1 in FIG. 2A. The encapsulation structure 3 includes a first encapsulation layer 31 and a second encapsulation layer 32 that are stacked. The first encapsulation layer 31 and the pins (22 and 23) are disposed in a same layer; and a thickness of the first encapsulation layer 31 is equal to a thickness of the pins (22 and 23). In this way, it is only necessary to change the original pattern when forming the pins (22 and 23), patterns of the first encapsulation layer 31 and the pins (22 and 23) can be formed by an one-time patterning process, without adding a separate process for preparing the first encapsulation layer 31, so that the preparation process flow can be simplified, the production cost can be saved, and the production efficiency can be improved. The second encapsulation layer 32 and the pads (11 and 12) are disposed in a same layer, and a surface of the second encapsulation layer 32 facing the driving backplane 1 is flush with a surface of the pads (11 and 12) facing the driving backplane 1. In this way, it is only necessary to change the original pattern when forming the pads (11 and 12), patterns of the second encapsulation layer 32 and the pads (11 and 12) can be formed by an one-time patterning process, without adding a separate process for preparing the second encapsulation layer 32, so that the preparation process flow can be simplified, the production cost can be saved, and the production efficiency can be improved.

In a specific implementation, the above light-emitting substrate according to embodiments of the present disclosure, as shown in FIG. 2A, further includes a connection layer (not shown) between the pads (11 and 12) and the pins (22 and 23). The light-emitting chips 2 are generally transferred to the driving backplane 1 by a mass transfer process. The pins (22 and 23) of the light-emitting chip 2 and the pads (11 and 12) of the driving backplane 1 are generally bonded by solder paste (including Sn, In, etc.), and then a reflow soldering process is performed so that the light-emitting chip 2 is bonded to the driving backplane 1, that is, a material of the connection layer may be solder paste. The light-emitting substrate further includes a heightening layer (not shown) between the first encapsulation layer 31 and the second encapsulation layer 32. In order to ensure effective encapsulation of the encapsulation structure 3 and the effective bonding of the light-emitting chip 2 and the driving backplane 1, a thickness of the heightening layer is equal to a thickness of the connection layer.

Preferably, a material of the heightening layer is same as a material of the connection layer, so that the heightening layer and the connection layer can be formed by an one-time process, without adding a separate process for preparing the heightening layer, so that the preparation process flow can be simplified, the production cost can be saved, and the production efficiency can be improved.

It should be noted that the bonding process of the light-emitting chip and the driving backplane is the same as that in the related art, which is not described in detail in the present disclosure.

In a specific implementation, when bonding the light-emitting chip 2 and the driving backplane 1, a connection layer (solder paste) may be disposed on the pins (22 and 23) of the light-emitting chip 2, or a connection layer (solder paste) may also be disposed on the pads (11 and 12) of the driving backplane 1. The electrical connection between the light-emitting chip 2 and the driving backplane 1 is then achieved by a reflow soldering process.

In a specific implementation, in the above light-emitting substrate according to embodiments of the present disclosure, as shown in FIG. 3A, a material type of the encapsulation structure 3 is not limited to use the original metal film layer of the light-emitting chip 2 and the driving backplane 1 as shown in FIG. 2A. The material of the encapsulation structure 3 can also be any other material that can achieve encapsulation performance and can ensure that thickness of the encapsulation structure is equal to the distance between the bottom surface of the side of the pads (11 and 12) facing away from the light-emitting main body 21 and the light-emitting main body 21. For example, the material of the encapsulation structure 3 may be an inorganic material or an organic material. Alternatively, the inorganic material may be silicon nitride, silicon oxide, silicon oxynitride, or the like; and the organic material may be a resin material or the like.

In a specific implementation, in the above light-emitting substrate according to embodiments of the present disclosure, as shown in FIGS. 3B and 3C, FIG. 3B is a structural diagram of a light-emitting chip 2 in FIG. 3A, and FIG. 3C is a structural diagram of a driving backplane 1 in FIG. 3A. The encapsulation structure 3 may be disposed at a side of the light-emitting main body 21. That is, an inorganic or organic material can be used to fabricate the encapsulation structure 3 at a side of the light-emitting main body 21. The thickness of the encapsulation structure 3 is equal to the distance between the bottom surface of the side of the pads (11 and 12) facing away from the light-emitting main body 21 and the light-emitting main body 21 after the light-emitting chip 2 and the driving backplane 1 are bonded.

In a specific implementation, in the above light-emitting substrate according to embodiments of the present disclosure, as shown in FIGS. 3D and 3E, FIG. 3D is a structural diagram of a light-emitting chip 2 in FIG. 3A, and FIG. 3E is a structural diagram of a driving backplane 1 in FIG. 3A. The encapsulation structure 3 can be disposed at a side of the driving backplane 1, that is, after the driving backplane 1 is fabricated, an inorganic material or organic material is used to fabricate the encapsulation structure 3 at a side of the driving backplane 1. The thickness of the encapsulation structure 3 is equal to the distance between the bottom surface of the side of the pads (11 and 12) facing away from the light-emitting main body 21 and the light-emitting main body 21 after the light-emitting chip 2 and the driving backplane 1 are bonded.

In a specific implementation, in the above light-emitting substrate according to embodiments of the present disclosure, as shown in FIG. 1, the light-emitting unit P may include a first light-emitting chip (e.g., a red light-emitting chip R), a second light-emitting chip (e.g., a green light-emitting chip G) and a third light-emitting chip (e.g., a blue light-emitting chip B) with different light-emitting colors. The pins (22 and 23) include an anode pin 22 and a cathode pin 23. Anode pins 22 (i.e., N electrodes) of the first light-emitting chip (R), the second light-emitting chip (G), and the third light-emitting chip (B) are disposed independently from each other. Cathode pins 22 (i.e., P electrodes) of the first light-emitting chip (R), the second light-emitting chip (G), and the third light-emitting chip (B) are the same pin. The light-emitting unit P in embodiments of the present disclosure includes light-emitting chips 2 of three colors of red, green and blue, that is, light-emitting chips 2 of three colors of red, green and blue are in a group, and an encapsulation structure 3 surrounds the periphery of each group. Of course, an encapsulation structure 3 can also surround the periphery of each light-emitting chip 2, and an encapsulation structure 3 can also surround two or three or more light-emitting units P, which is not limited in the present disclosure.

In a specific implementation, in the above light-emitting substrate according to embodiments of the present disclosure, as shown in FIGS. 2A and 3A, the driving backplane 1 may be a silicon-based driving backplane. The driving backplane 1 may include a substrate 13; and a barrier layer 14, a buffer layer 15, an active layer 16, a first gate insulating layer 17, a first gate layer 18, a second gate insulating layer 19, a second gate layer 20, an interlayer insulating layer 24, a first source-drain metal layer 25, a planarization layer 26, and a second source-drain metal layer (11 and 12) which are sequentially stacked between the substrate 13 and the light-emitting chip 2. The first gate layer 18 includes a gate G, and a lead 181. The first source-drain metal layer 25 includes a source S, a drain D, a data line 251, and a ground electrode 252. The active layer 16, the gate G, the source S, and the drain D constitute a thin film transistor. The anode pad (11) is electrically connected with the source S through a first via hole V1 penetrating the planarization layer 26. The cathode pad (12) is electrically connected with the ground electrode 252 through a second via hole V2 penetrating the planarization layer 26. The data line 251 is electrically connected with the lead 181 through a third via hole V3 penetrating the interlayer insulating layer 24 and the second gate insulating layer 19. The lead 181 is electrically connected with a transfer electrode 27 through a fourth via hole V4 penetrating the first gate insulating layer 17, the buffer layer 15, the barrier layer 14 and the substrate 13. The transfer electrode 27 is configured to input an external electrical signal to the data line 251.

In a specific implementation, in the above light-emitting substrate according to embodiments of the present disclosure, as shown in FIGS. 2A and 3A, the light-emitting main body 21 may include an N-type semiconductor layer, a quantum well layer and a P-type semiconductor layer. The N-type semiconductor layer is electrically connected with the anode pin 22. The P-type semiconductor layer is electrically connected with the cathode pin 23. When the light-emitting chip 2 emits light, the driving current is input to the light-emitting chip 2 through the thin film transistor, and the specific light-emitting principle is the same as that of the related art, which is not described in detail here.

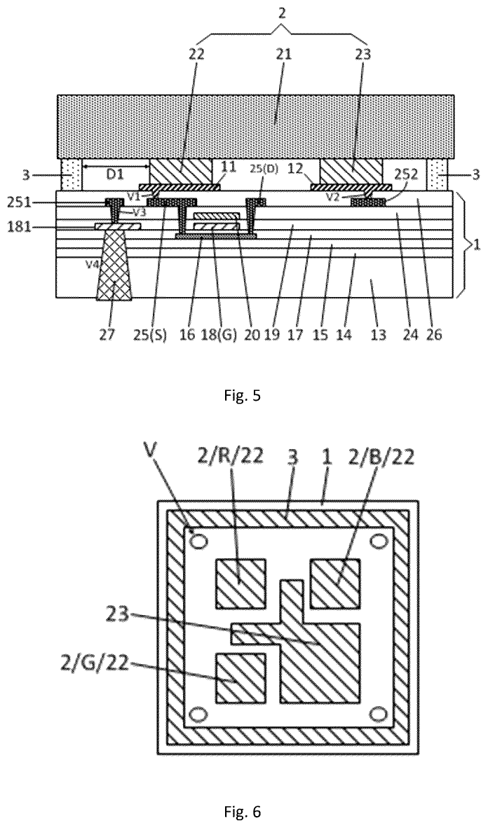

In a specific implementation, in the above light-emitting substrate according to embodiments of the present disclosure, as shown in FIGS. 4 and 5, the driving backplane 1 includes a via hole region V (e.g. V1, V2, V3, V4) disposed at an outer side of the light-emitting unit P. A certain segment difference exists between the via hole region V and other non-via hole regions. In order to avoid gaps existing during subsequent sealing due to the segment difference, resulting in that the encapsulation structure 3 cannot seal the light-emitting unit P, in embodiments of the present disclosure, an orthographic projection of the encapsulation structure 3 on the substrate 13 of the driving backplane 1 and an orthographic projection of the via hole region V on the substrate 13 of the driving backplane 1 do not overlap, so that the encapsulation structure 3 can avoid the position with the segment difference of the driving backplane 1 to improve the sealing performance of the encapsulation structure 3.

In a specific implementation, in the above light-emitting substrate according to embodiments of the present disclosure, as shown in FIG. 6, FIG. 6 is a schematic diagram of a planar structure corresponding to an encapsulation structure 3 in FIGS. 4 and 5, and a shape of the encapsulation structure 3 is a regular closed ring. That is, the encapsulation structure 3 may be disposed to surround the via hole region V to avoid the overlap of the orthographic projections of the encapsulation structure 3 and the via hole region V.

Optionally, as shown in FIGS. 1 and 6, an annular shape of the encapsulation structure 3 is square, and of course, the annular shape of the encapsulation structure 3 can also be other annular shapes such as a circle.

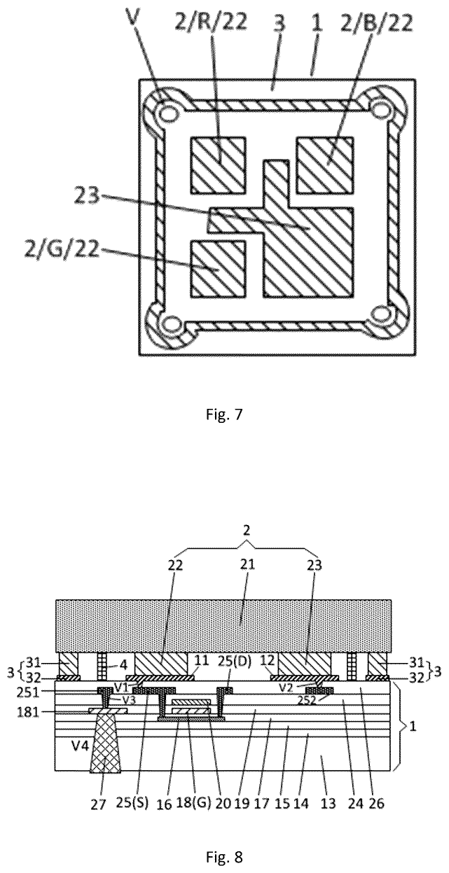

In a specific implementation, in the above light-emitting substrate according to embodiments of the present disclosure, as shown in FIG. 7, FIG. 7 is a schematic diagram of another planar structure corresponding to an encapsulation structure 3 in FIGS. 4 and 5. The shape of the encapsulation structure 3 may also be an irregular closed ring avoiding the via hole region V. In this way, the encapsulation structure 3 only needs to avoid the via hole region V in the via hole region V, and the surrounding area of the encapsulation structure 3 does not need to be enlarged as shown in FIG. 6. The resolution of the light-emitting substrate can be improved. Specifically, the shape of the encapsulation structure 3 in the via hole region V is, for example, an arc, but is certainly not limited thereto as long as the via hole region V can be avoided.

Specifically, a width of the encapsulation structure 3 is not limited, and can be determined according to the actual arrangement capability and space. The encapsulation structure 3 surrounds the whole pixel unit group and can be a closed ring such as a circle or a square.

In a specific implementation, in the above light-emitting substrate according to embodiments of the present disclosure, as shown in FIGS. 1, 2A, 3A, 4 and 5, a distance D1 between the encapsulation structure 3 and the pins (22 and 23) is greater than or equal to 5 μm, a width W of the encapsulation structure 3 is greater than or equal to 10 μm, and a distance D2 between encapsulation structures 3 outside two adjacent light-emitting units P is greater than or equal to 3 μm.

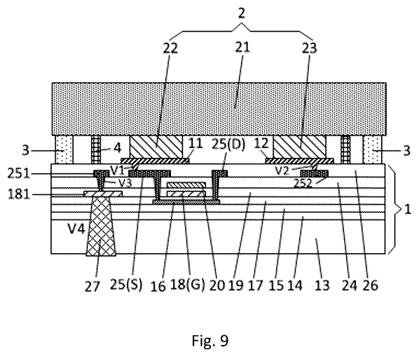

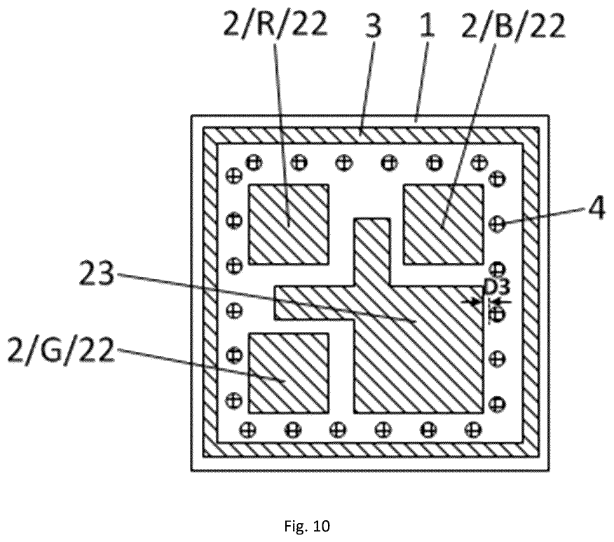

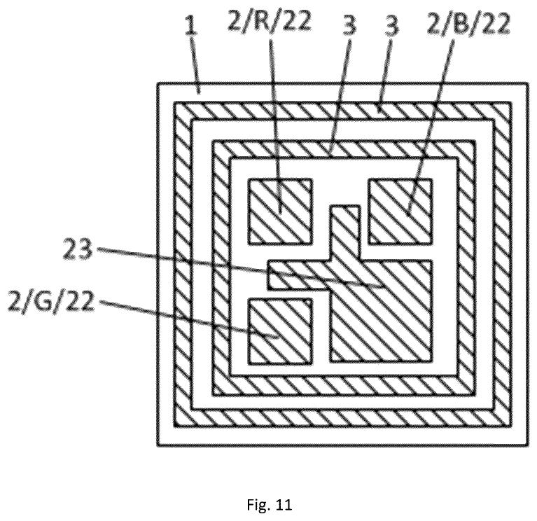

In a specific implementation, in the above light-emitting substrate according to embodiments of the present disclosure, as shown in FIGS. 8, 9 and 10, FIGS. 8 and 9 are schematic diagrams of other two sectional structures of a light-emitting substrate, respectively. FIG. 10 is a schematic diagram of another planar structure corresponding to an encapsulation structure 3 in FIGS. 8 and 9. The light-emitting substrate further includes supporting structures 4 independently disposed between the encapsulation structure 3 and the light-emitting chip 2. A thickness of the supporting structure 4 is equal to a thickness of the encapsulation structure 3. Therefore, the supporting performance of the light-emitting substrate can be improved, and the overall reliability and the stability of the device structure can be further improved.

In a specific implementation, in the above light-emitting substrate according to embodiments of the present disclosure, as shown in FIG. 10, a plurality of supporting structures 4 are provided, and the plurality of supporting structures 4 are uniformly disposed between the encapsulation structure 3 and the light-emitting chip 2. In this way, the supporting performance of the light-emitting substrate in each region is approximately the same, and the overall stability of the device structure is improved.

In a specific implementation, in order to meet the alignment precision design of the driving backplane and the light-emitting chip, in the above light-emitting substrate according to embodiments of the present disclosure, as shown in FIG. 10, a distance D3 between the supporting structure 4 and the pins (22 and 23) is greater than or equal to 1.2 μm.

In a specific implementation, in the above light-emitting substrate according to embodiments of the present disclosure, as shown in FIG. 10, a material of the supporting structure 4 may be an organic material, such as a resin material. A shape of an orthographic projection of the supporting structure 4 on the driving backplane 1 is a circle. Of course, the shape of the orthographic projection of the supporting structure 4 on the driving backplane 1 can also be a rectangle, a triangle, or other shapes.

In a specific implementation, as shown in FIGS. 8 and 9, before the driving backplane 1 and the light-emitting chip 2 are bonded, the supporting structure 4 may be disposed at a side of the driving backplane 1 or at a side of the light-emitting chip 2.

In a specific implementation, in the above light-emitting substrate according to embodiments of the present disclosure, as shown in FIGS. 1, 6, 7 and 10, an encapsulation structure 3 is disposed at an outer side of each light-emitting unit P. In order to improve the encapsulation performance of the light-emitting unit P and the supporting performance of the light-emitting substrate, the number of encapsulation structures 3 disposed at an outer side of each light-emitting unit P may be more than one. As shown in FIG. 11, the number of the encapsulation structures 3 disposed at an outer side of each light-emitting unit P is two, and the encapsulation structures at an outer side of the same light-emitting unit P are disposed at intervals.

In conclusion, the light-emitting substrate according to embodiments of the present disclosure can realize the independent protection and encapsulation of the light-emitting unit, avoid liquid from infiltrating into the device in the subsequent electroplating and etching processes, and improve the overall reliability and the structural stability of the device. In addition, the light-emitting substrate provided by the present disclosure has a simple structure and can be realized through the existing process. In addition, the encapsulation structure of the present disclosure may be fabricated by using the own structure of the light-emitting chip and the driving backplane, the single edge sealing process is reduced, the cost is reduced, and the stability of the whole structure and the reliability of the device can be improved by adopting the encapsulation structure.

In a specific implementation, in the light-emitting substrate according to embodiments of the present disclosure, the light-emitting chip may be a Micro LED. Due to the small size of the Micro LED, the pixel resolution of the light-emitting substrate can be improved. In particular, the size of the Micro LED is generally less than 100 μm. Of course, the light-emitting chip may also be other LEDs such as a Mini LED, which is not limited in the present disclosure. When the light-emitting chip is a Mini LED, the size of the Mini LED is 100 μm to 200 μm.

The above light-emitting substrate according to embodiments of the present disclosure takes a display substrate as an example, and of course, the light-emitting substrate can also be a backlight substrate. If the light-emitting substrate is a backlight substrate, the light-emitting chip is used for providing a light source, to corporate with the passive display panel to realize display.

The light-emitting colors included in the light-emitting substrate are not limited herein. The light-emitting color of the light-emitting substrate may include any one of red, green, or blue. The light-emitting colors of the light-emitting substrate can simultaneously include three light-emitting colors of red, green and blue. Of course, the light-emitting color of the light-emitting substrate can also include only one light-emitting color, for example, only red, or only green, or only blue. The details can be determined according to actual requirements.

In a specific implementation, the light-emitting substrate according to embodiments of the present disclosure may further include other functional film layers known to those skilled in the art, which will not be listed here.

Based on the same inventive concept, an embodiment of the present disclosure further provides a display device including any of the above light-emitting substrates according to embodiments of the present disclosure. The display device can be any product or component with a display function, for example, a mobile phone, a tablet computer, a television, a display, a notebook computer, a digital photo frame, a navigator or the like. For the implementation of the display device, reference may be made to the above embodiments of the light-emitting substrate, and the repetition thereof is omitted.

Embodiments of the disclosure provide a light-emitting substrate and a display device. By disposing the encapsulation structure which surrounds the light-emitting unit and is between the driving backplane and the light-emitting unit, each light-emitting unit can be protected and encapsulated independently to form an integral sealing structure of the light-emitting unit, effectively preventing liquid from infiltrating into the gap between the light-emitting chip and the driving backplane in the subsequent processes of electroplating, etching, cleaning and the like, so that the overall reliability and the stability of the device structure can be improved. Meanwhile, the encapsulation structure can also play a role in supporting the light-emitting substrate, and improve the structural stability of the light-emitting substrate.

Although preferred embodiments of the present disclosure have been described, those skilled in the art may make additional changes and modifications to these embodiments once they are aware of the basic inventive concept. Therefore, the claims intend to include preferred embodiments as well as all these changes and modifications falling within the scope of the present disclosure.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A light-emitting substrate, comprising:
a driving backplane;
a plurality of light-emitting units at a side of the driving backplane, wherein each of the plurality of light-emitting units comprises at least one light-emitting chip; and
an encapsulation structure disposed between the driving backplane and the light-emitting unit and surrounding the light-emitting unit.

2. The light-emitting substrate according to claim 1, wherein the driving backplane has a plurality of pads, the light-emitting chip comprises a light-emitting main body and pins, and the light-emitting main body is electrically connected with corresponding pads through the pins; wherein,
the encapsulation structure is disposed between the light-emitting main body and the driving backplane, and a thickness of the encapsulation structure is equal to a distance between a bottom surface of a side of the pad facing away from the light-emitting main body and the light-emitting main body.

3. The light-emitting substrate according to claim 2, wherein the encapsulation structure comprises a first encapsulation layer and a second encapsulation layer that are stacked;
the first encapsulation layer and the pin are disposed in a same layer, and a thickness of the first encapsulation layer is equal to a thickness of the pin; and
the second encapsulation layer and the pad are disposed in a same layer, and a surface of the second encapsulation layer facing the driving backplane is flush with a surface of the pad facing the driving backplane.

4. The light-emitting substrate according to claim 3, further comprising a connection layer between the pads and the pins, and a heightening layer between the first encapsulation layer and the second encapsulation layer;
wherein a thickness of the heightening layer is equal to a thickness of the connection layer.

5. The light-emitting substrate according to claim 4, wherein a material of the heightening layer is same as a material of the connection layer.

6. The light-emitting substrate according to claim 2, wherein a material of the encapsulation structure is an inorganic material or an organic material.

7. The light-emitting substrate according to claim 6, wherein the encapsulation structure is disposed at a side of the light-emitting main body; or the encapsulation structure is disposed at a side of the driving backplane.

8. The light-emitting substrate according to claim 1, wherein the driving backplane comprises a via hole region at an outer side of the light-emitting unit; and
an orthographic projection of the encapsulation structure on a substrate of the driving backplane and an orthographic projection of the via hole region on the substrate of the driving backplane do not overlap.

9. The light-emitting substrate according to claim 8, wherein a shape of the encapsulation structure is a regular closed ring.

10. The light-emitting substrate according to claim 8, wherein a shape of the encapsulation structure is an irregular closed ring avoiding the via hole region.

11. The light-emitting substrate according to claim 2, wherein a distance between the encapsulation structure and the pin is greater than or equal to 5 μm;
a width of the encapsulation structure is greater than or equal to 10 μm; and
a distance between encapsulation structures outside two adjacent light-emitting units is greater than or equal to 3 μm.

12. The light-emitting substrate according to claim 2, further comprising supporting structures independently disposed between the encapsulation structure and the light-emitting chip;
wherein a thickness of the supporting structure is equal to a thickness of the encapsulation structure.

13. The light-emitting substrate according to claim 12, wherein a plurality of supporting structures are provided; and
the plurality of supporting structures are uniformly disposed between the encapsulation structure and the light-emitting chip.

14. The light-emitting substrate according to claim 13, wherein a distance between the supporting structure and the pin is greater than or equal to 1.2 μm.

15. The light-emitting substrate according to claim 14, wherein a material of the supporting structure is an organic material; and
a shape of an orthographic projection of the supporting structure on the driving backplane comprises a rectangle or a circle.

16. The light-emitting substrate according to claim 1, wherein the encapsulation structure is disposed at an outer side of each of the plurality of light-emitting units.

17. The light-emitting substrate according to claim 1, wherein a quantity of encapsulation structures disposed at an outer side of each of the plurality of light-emitting units is more than one; and
the encapsulation structures at the outer side of a same light-emitting unit are disposed at intervals.

18. The light-emitting substrate according to claim 1, wherein the light-emitting unit comprises a first light-emitting chip, a second light-emitting chip and a third light-emitting chip with different light-emitting colors;
pins comprise an anode pin and a cathode pin;
anode pins of the first light-emitting chip, the second light-emitting chip and the third light-emitting chip are disposed independently from each other; and
cathode pins of the first light-emitting chip, the second light-emitting chip and the third light-emitting chip are a same pin.

19. The light-emitting substrate according to claim 1, wherein the light-emitting chip comprises a micro light-emitting diode (Micro LED) or a mini light-emitting diode (Mini LED).

20. A display device, comprising the light-emitting substrate according to claim 1.
